(19) United States
(12) Patent Application Publication
(10) Pub. No.: US 2009/0123079 A1
(43) Pub. Date: May 14, 2009

(54) REDUCTION OF COMPRESSION ARTEFACTS IN DISPLAYED IMAGES

(75) Inventor: Ihor Olehovych Kirenko, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 12/158,049

(22) PCT Filed: Dec. 12, 2006
(86) PCT No.: PCT/IB06/54774

§ 371 Date: Jun. 19, 2008

(30) Foreign Application Priority Data
Dec. 21, 2005 (EP) 05112598.7

(51) Int. Cl. G06K 9/36; H04N 5/66; G06K 9/40; H05K 11/00

(52) U.S. Cl. 382/233; 348/739; 382/264; 455/344; 348/E05.133

(57) ABSTRACT

In a method, receiver and display device a compressed data stream is decompressed. Decompression may cause ringing effect. In order to reduce ringing effects an analysis window (AWH, AWV) is used, which is divided into two sub-areas (AWH1, AWH2, AWV1, AWV2) along a dividing line d. For each of the sub areas a maximum pixel value gradient (MAXD1, MAXD2) is determined, wherein gradients are determined in two directions. If the maximum of all gradients (max(MAXD1, MAXD2) exceeds a threshold (max(MAXD1,MAXD2)>Tmax), low pass filtering is applied, provided that the difference between the maximum gradients for each of the areas is above a threshold (æMAXD2−MAXD1æ>T1). The direction of low pass filtering is determined by the sign of the difference of the between the maximum pixel value gradient for the sub-areas.

The present invention relates to a method of processing a compressed image data stream in which method ringing is reduced.

The present invention also relates to a display device comprising a receiver arranged for receiving a compressed data stream for displaying an image, the receiver comprising a ringing reducer for reduction of ringing artifacts in a displayed decompressed image.

The present invention also relates to a receiver arranged for receiving a compressed data image stream for displaying an image, the receiver comprising a ringing reducer for reduction of ringing artifacts in a displayed decompressed image.

Image display systems often receive compressed data streams. A variety of “lossy” video compression techniques are known to reduce the amount of image data that must to be stored or transmitted. Sophisticated compression schemes such as JPEG, MPEG or Wavelet-based attempt to truncate spatial frequency information that is not crucial to perception of a viewer. With high compression ratios, image artifacts may appear in the decompressed image. One of such artifacts is ringing, in which spurious ripples appear around edges or abrupt contrast changes.

Ringing artifacts result from a loss of high spatial frequency information necessary to accurately represent the edge. The human visual system is known to be sensitive to ringing artifacts to the same extent as to blocking artifacts.

Conventionally a low-pass filtering has been used to remove the ringing artifacts from a decompressed picture. However, a low-pass filter also removes the picture details, which causes blurring artifacts. There is, therefore, a need for an adaptive method of suppressing ringing artifacts that commonly arise in decompressed pictures. Some methods are known for suppressing ringing artifacts in decompressed images.

U.S. Pat. No. 6,668,097 describes a system using algorithms for detecting edges to identify object edges and to apply smoothing along the detected edges. The disadvantage of such an approach is that a high computational complexity is required to detect and classify edges, and a sequential nature of processing (first, an object should be detected and then adaptive filtering is applied). But the main disadvantage of the algorithm is caused by a low robustness of an edge detection mechanism, on which the whole algorithm is based. In order to differentiate an object edge from the texture, noise or even ringing ripples, the analysis window should be large enough. A big size of an analysis window increases latency, complexity and memory requirements of the algorithm implementation (especially in case of hardware implementation); moreover, short strong edges with lengths smaller than the size of the analysis window, will not be detected as an edge, thus will not be selected for filtering, although they still may generate ringing.

US Patent Application 2004012582 describes a different approach in which ringing-like areas in the picture are detected and low-pass filtering is applied to those areas. The detection is implemented by computing a local variance/deviation for each pixel in an image based on neighboring pixels in the analyzed window. The area is regarded to be comprising ringing, if a variance of pixels within analyzed window is higher than some predefined threshold. The bottleneck of such approach is a robust differentiation between “ringing-like” areas from the areas with noise or image texture, because all those areas may have the same level of spatial activity (the same pixel variance).

It is an object of the invention to provide a system, display device and method as described in the opening paragraphs in which a relatively simple, robust method of reduction of ringing is applied while yet preserving fine details of pictures from being overly blurred.

To this end the method is characterized in that an area of an image is selected and divided into two sub-areas of substantially equal size along a dividing line, and a first maximum pixel value gradient between adjacent pixels is established for one of the sub-areas and a second maximum pixel value gradient for the other sub-area and low pass filtering is applied on the condition that

the maximum of the first and second maximum pixel value gradient is above a first threshold and

a relation between the first and second maximum pixel value gradient meets a second threshold

wherein the low pass filtering is performed perpendicular to the dividing line and wherein the low pass filtering is applied in dependence on the sign of the difference between the first and second maximum pixel value gradients.

The low pass filtering is only applied if the maximum pixel value gradient within the analysis area is above a threshold, i.e. low pass filtering is only applied when the maximum of the first and second maximum pixel value gradients is above a first threshold. This provides the advantage that filtering is only applied around strong edges or sudden changes in values.

Furthermore low pass filtering is only applied if the relation between the maximum pixel value gradients of the sub-areas meets a second threshold. Ringing typically occurs when in a sub-area a strong edge or large change is next to a relatively quiet sub-area. Ringing reduction is not applied if the two sub areas have comparable maximum pixel differences, which could be for instance the case in texture. The relation could be that the absolute difference between the maximum pixel value gradients is larger that a second threshold. The relation could also be a ratio between the maximum pixel value gradients, in which case the ratio should be above a second threshold, or below a second threshold depending on the ratio taken.

Ringing typically occurs next to strong edge or abrupt change in a direction perpendicular to the change going away from the change. The sign of the difference between the first and second maximum pixel value difference indicates in which of the two sub areas the sudden change or edge occurs. Low pass filtering is applied 1-dimensionally and in a fixed direction, namely perpendicular to the dividing line in dependence of the difference. The method provides for a simple and robust method for reducing ringing which does not affect texture.

The simplicity of the algorithm, which needs only simple calculations and a simple analysis window, e.g. no complex edge determination and edge direction determination, provides great robustness and speed to the method. There is no edge direction detection and low pass filtering is performed 1-dimensionally simply in a direction perpendicular to the dividing line, thus a very simple algorithm is used. Yet experiments have shown that ringing is effectively reduced, without unduly negative effects on image features such as texture. Ringing effect not associated with edges, but for instance with very small features, with sizes significantly smaller than the DCT block size, are also effectively reduced, whereas anti-ringing methods based on edge direction determination often do not reduce ringing in such circumstances, since true edges cannot be distinguished.

The display device and receiver in accordance with the invention comprises a ringing reducer for performing the algorithm in accordance with the invention.

The method in accordance with the invention is preferably done in two perpendicular directions, e.g. first horizontal filtering followed by vertical filtering.

The area is typically an area of n*m pixels, wherein n is the number of pixels perpendicular to the dividing line, and wherein n is preferably even and m is preferably odd. Preferably n is 6 and m is 3. Even with such small windows, wherein each sub-area is only 3×3 pixels very good results have been obtained.

The first threshold may be a fixed threshold. In such embodiments the low pass filtering is only applied if the maximum gradient is above a fixed value.

In embodiments the first threshold is dependent on the value of the pixel values in the area. Thus for instance the higher an average pixel value of the area, the higher the first threshold is. The first threshold is then a relative threshold.

The second threshold may also be fixed or dependent on the pixel values in the area.

These and further aspects of the invention will be explained in greater detail by way of example and with reference to the accompanying drawings, in which

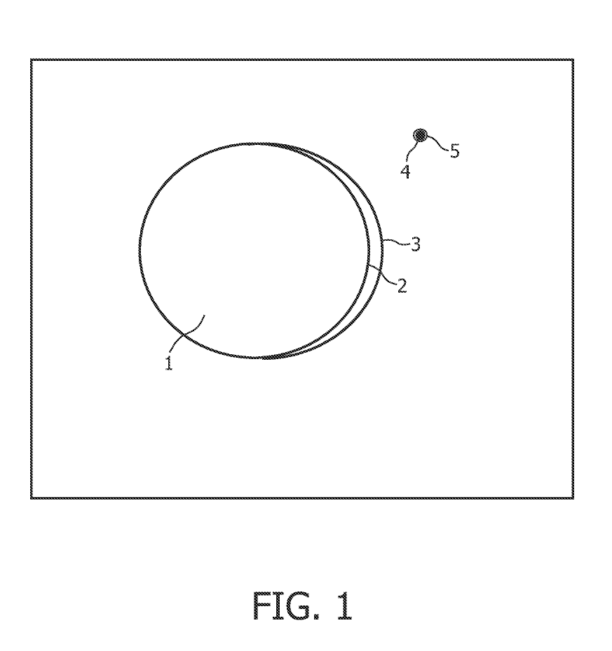

FIG. 1 schematically illustrates ringing

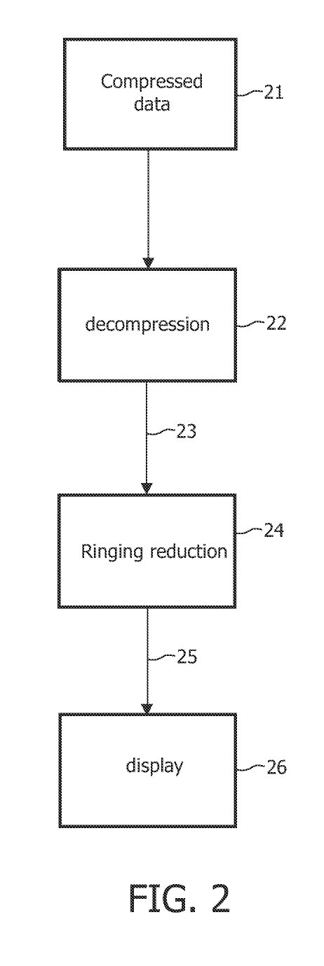

FIG. 2 schematically illustrates a method in accordance with the invention

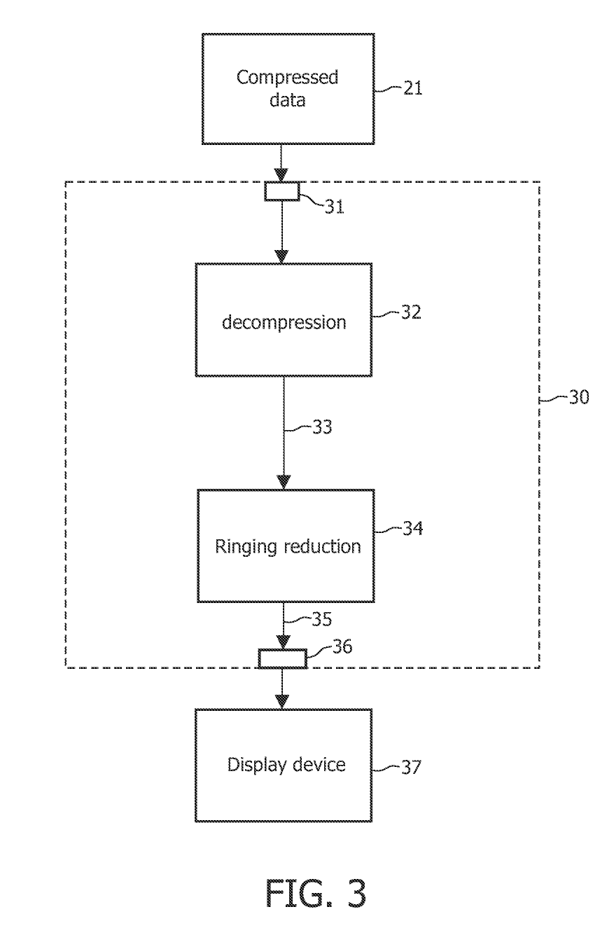

FIG. 3 schematically illustrates a device in accordance with the invention.

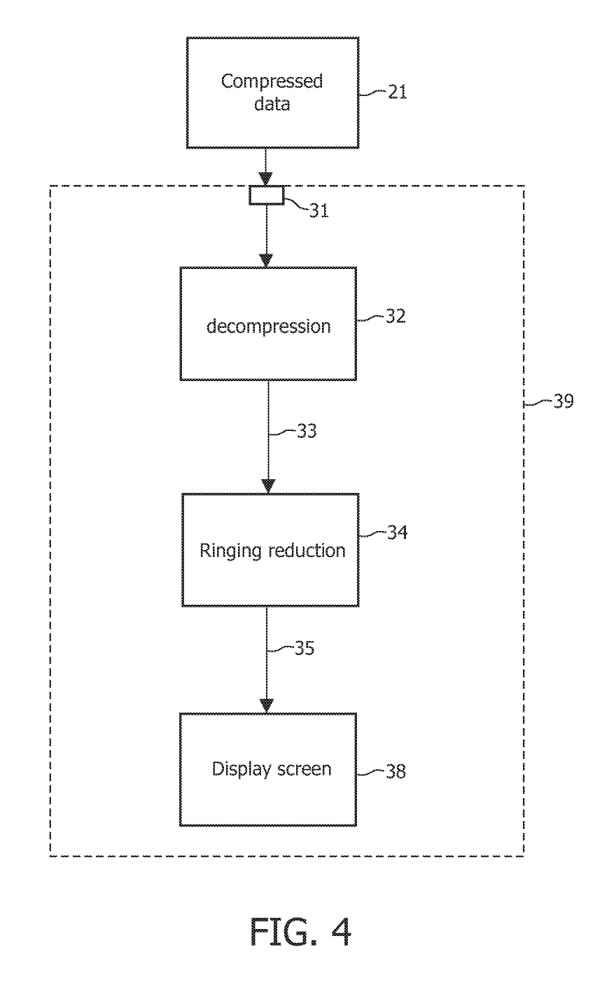

FIG. 4 schematically illustrates a display device in accordance with the invention

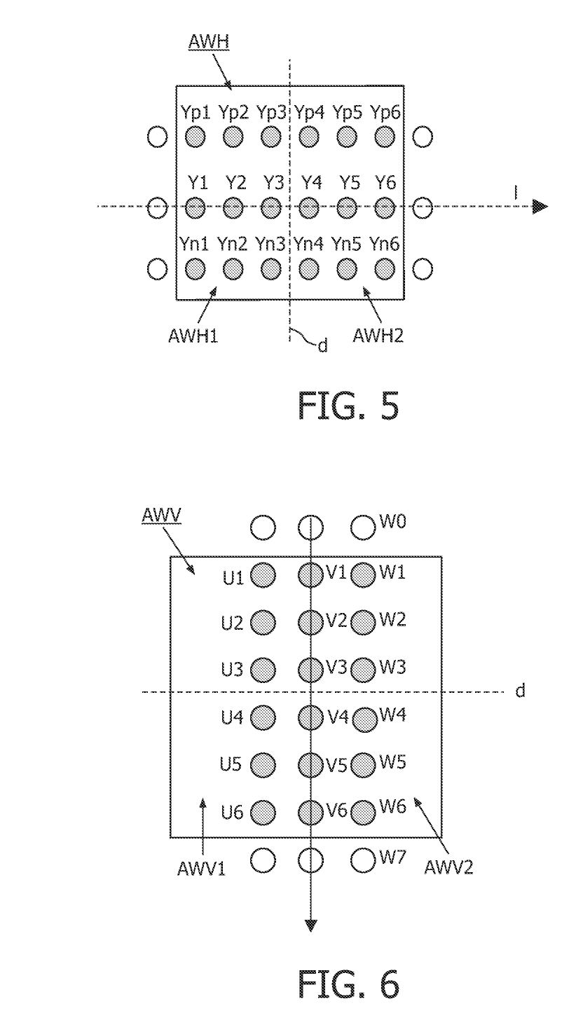

FIGS. 5 and 6 schematically illustrate details of the algorithm used in the method and devices in accordance with the invention for horizontal and vertical analysis respectively.

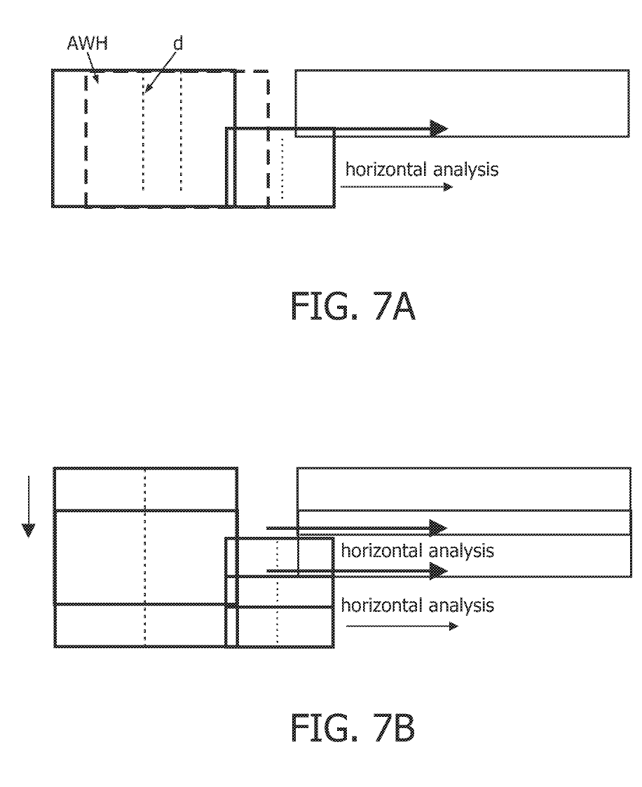

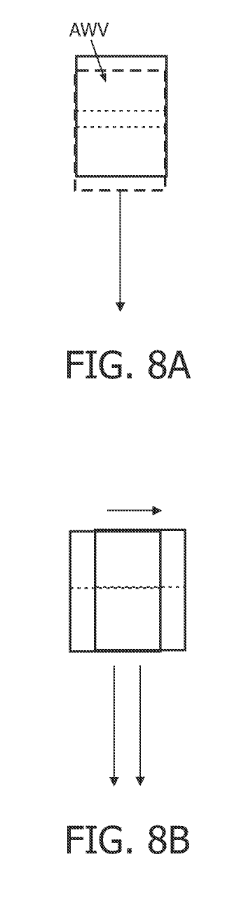

FIGS. 7A, 7B, 8A and 8B schematically illustrate scanning of analysis windows over an image.

The figures are not drawn to scale. Generally, identical components are denoted by the same reference numerals in the figures.

The present invention will now be described more fully hereinafter with reference to the accompanying drawings, in which preferred embodiments of the present invention are shown. This invention may, however, be embodied in many different forms and should not be construed as limited to the embodiment set forth herein; rather, these embodiments are provided so that this disclosure will be thorough and complete, and will fully convey the scope of the invention to those skilled in the art. Like numbers refer to like elements throughout.

Compression techniques are often used to compress the data stream, i.e. reduce the amount of data within the data stream. In particular, consumer recorder devices (DVD recorders, hard-disk recorders etc.) use digital compression algorithms to provide digitally compressed streams such as MPEG2 streams. Such compression techniques may be lossless techniques, but often, when an appreciable amount of compression is used, some loss of data is deemed acceptable. Typically data compression techniques are arranged such that the loss in data is kept relatively small so that not much visible effect of the data compression is seen in the decompressed displayed image. However, especially with high compression ratios, image artifacts may appear in the decompressed image. One of such artifacts is ringing, in which spurious ripples appear around edges or abrupt contrast changes.

Ringing artifacts result from a loss of high spatial frequency information necessary to accurately represent the edge. The human visual system is known to be sensitive to ringing artifacts to the same extent as to blocking artifacts.

FIG. 1 schematically illustrates the visual effect of ringing. In an image an object 1 comprises an edge 2. Around or near the edge 2 a faint ripple 3 is visible. A similar effect 5 is visible around sharp point or small objects 4.

FIG. 2 schematically illustrates a method in accordance with the invention. A compressed image data stream 21, which could be video, but also text and/or still images, is decompressed in decompression method step 21. After decompression the decompressed data stream 23, if directly send to a display screen for display would show ringing. To reduce the ringing the data stream is subjected to a ringing reduction method step 24. This may be done in a hardware or software form. The resulting data stream 25 is sent to a display screen 26 for display.

FIG. 3 schematically illustrates a device 30 in accordance with the invention. A compressed image data stream 21, which could be video, but also text and/or still images, is an input for input 31 of device 30. The data stream is decompressed in a decompression method step 21 in decompressor 32. After decompression the decompressed data stream 33, if directly send to a display screen for display would show ringing. To reduce the ringing the data stream is subjected to a ringing reduction method step in ringing reducer 34. This may be done in a hardware or software form. The resulting data stream 35 is an output at output 36 of device 30 and may be sent to a display screen 26 for display.

In this example the device converts the incoming compressed input data stream 21 received at input 31 into a decompressed output data stream 35 at an output 35 of the device. Such devices may for instance be receivers which are coupled between an incoming signal, such as cable, and a display device such as a TV.

FIG. 4 illustrates a display device in accordance with the invention. This device is comparable to the receiver shown in FIG. 3, except for the fact that the display screen 38 is comprised in the device.

Display device could be, but are not restricted to, one of the following: TV's, monitors, handheld devices such as laptops, mobile telephone.

FIG. 5 illustrates the method in accordance with the invention.

The present invention provides a method for reduction of ringing artifact by means of adaptive processing based on local spatial analysis. The algorithm aims to remove only visible ringing around strong edges without blurring image texture or the edges themselves. The algorithm allows simple hardware or software implementation.

The proposed algorithm consists of two parts. The algorithm is applied to an image in the raster-scan order.

A first part of the algorithm and method in accordance with the invention is a detection of the areas with location of ringing artifacts. In order to detect those areas a spatial analysis area AWH (horizontal analysis window) of pixels is analyzed. The area is schematically shown in FIG. 5 by the grey dots Yp1, Yp2 etc. This m*n, in this example 6×3, analysis area is divided by dividing line d into two sub-areas AWH1, AWH2 with sizes m/2*n, in this example 3×3. For each of the obtained sub-areas the maximum gradient (MAXD1 or MAXD2) between a pair of adjacent pixels is found:

MAXD1=max(|Y1−Y2|,|Y2−Y3|,|Yp1−Y1|,|Yn1−Y1|,|Yp2−Y2|,|Yn2−Y2|,|Yp3−Y3|,|Yn3−Y3|);

MAXD2=max(|Y4−Y5|,|Y5−Y6|,|Yp4−Y4|,|Yn4−Y4|,|Yp5−Y5|,|Yn5−Y5|,|Yp6−Y6|,|Yn6−Y6|);

In this example the maximum gradient is simply the difference in pixel values.

The size of the analysis window may be larger, but preferably not larger than a block size, e.g. 8×8.

The de-ringing is applied only to the pixels around strong edges. This means that the filtering is performed only if max(MAXD1, MAXD2)>Tmax, where Tmax thus serves a first threshold for application of the de-ringing. This provides the advantage that filtering is only applied around strong edges or sudden changes in values.

The first threshold may be a fixed threshold. In such embodiments the low pass filtering is only applied if the maximum gradient is above a fixed value.

In embodiments the first threshold is dependent on the value of the pixel activity in the area. Thus for instance the higher an average gradient of pixel pairs within the area, the higher the first threshold is. The first threshold is then a relative threshold.

In experiments Tmax was taken to be Tmax=40. Such a high value of Tmax makes sure, that neither texture nor blocking edges will be detected as origins of ringing artifacts.

The second threshold is given by the fact that the difference between MAXD1 and MAXD2 is above a second threshold T1. Ringing typically occurs and is most visible when in a sub-area a strong edge or large change occurs, thus an area with relatively high MAXD1 or MAXD2, next to a relatively quiet sub-area, thus an area with a relatively small MAXD2 or MAXD1. Ringing reduction is not applied if the two sub-areas have comparable maximum pixel differences, which could be for instance the case in texture. Thus filtering, in this example, is only applied if there exist a relation between MAXD1 and MAXD2 wherein the absolute difference between the first and second maximum pixel value gradients is larger that a second threshold, i.e. |MAXD1−MAXD2|>T1

Thirdly, the obtained maximum gradient values MAXD1 and MADX2 are used to define the direction for the adaptive low-pass filtering:

If MAXD1−MAXD2>T1, (MAXD1 thus being larger than MAXD2) then the filtering will take place in the direction from pixels Y4-Y6 to pixels Y1-Y3.

If MAXD2−MAXD1>T1, (MAXD2 thus being larger than MAXD1) then the filtering will take place in the direction from pixels Y1-Y3 to pixels Y4-Y6.

Although two-dimensional spatial window is used for the analysis, the adaptive low-pass filtering at the next step of the algorithm is implemented only one-dimensionally, along horizontal line 1 though pixel Y1, Y2 etc. Horizontal filtering in the detected areas over whole image is performed first followed by a vertical filtering.

The simplicity of the algorithm, which needs only simple calculations and a simple analysis window, e.g. no complex edge determination and edge direction determination, provides great robustness and speed to the method. There is no edge direction detection and low pass filtering is performed 1-dimensionally simply in a direction 1 perpendicular to the dividing line d, thus a very simple algorithm is used. Yet experiments have shown that ringing is effectively reduced, without unduly negative effects on image features such as texture. Ringing effect not associated with edges, but for instance with very small features, with sizes significantly smaller than a DCT block size, are also effectively reduced, whereas anti-ringing methods based on edge direction determination often do not reduce ringing in such circumstances, since true edges cannot be distinguished.

The following code explains the proposed filtering method.

| | |
|---|---|
| If ((MAXD1 − MAXD2)> T1 and max(MAXD1,MAXD2) > Tmax) | (1) |
| { | |
| if ( \|Y4 − Y5\|<T2 and \|Y3 − Y4\|<T2 and \|Y5 − Y6\|<T3) | |
| Y3’ = (Y3*2 + Y4 + Y5 + Y6 )/5 ; | |
| else if ( \|Y4 − Y5\|<T3 and \|Y3−Y4\| < T3) | |
| Y3’ = (Y3*2 + Y4 + Y5 )/4 ; | |
| if ( \|Y4−Y5)<T2 and \|Y5−Y6\|<T2 ) | |
| { | |
| Y4’ = (2*Y4 + Y5 + Y6 )/4 ; | |
| Y5’ = (2*Y5 + Y6)/3 ; | |
| } | |
| else if ( \|Y4−Y5\| < T3 ) | |
| Y4’ = \|2*Y4 + Y5\|/3 ; | |
| } | |
| if ( (MAXD2 − MAXD1)>T1 and max(MAXD1,MAXD2) > Tmax ) | (2) |
| { | |
| if ( \|Y3−Y2\|<T2 and \|Y3−Y4\| <T2 and \|Y2−Y1\|<T2 ) | |
| Y4’ = (2*Y4 + Y3 + Y2 + Y1)/5 ; | |
| else if ( \|Y3−Y2\|<T3 and \|Y3−Y4\| <T3 ) | |
| Y4’ = (2*Y4 + Y3 + Y2 )/4 ; | |
| if ( \|Y3−Y2\| <T2 and \|Y2−Y1\|<T2) | |
| { | |
| Y3’ = (2*Y3 + Y2 + Y1)/4 ; | |
| Y2’ = (2*Y2 + Y1 )/3 ; | |
| } | |
| else if ( \|Y3−Y2\|<T3 ) | |
| Y3’ = ((2*Y3 + Y2 )/3 ; | |
| } | |

Y2′-Y5′-output values of the filtered luminance components.

According to the invention low-pass filtering is applied perpendicular to the sub-window, which comprises a maximum gradient. The thresholds T2 and T3 in the above formulae are used to protect image texture, located around strong object edges, from being filtered. It is assumed that if the value of pixels pair gradient (Y3-Y2, or Y2-Y2) is smaller than the threshold T2 or T3, then there is no texture around the edge, and thus, low-pass filtering may be applied. Because the severity of ringing and the visibility of texture depend on the global quality of the image, values of the thresholds T2 and T3 preferably depend on image quality or compression ratio (bit-rate). Higher values of T2 and T3 should be chosen if higher compression was used (lower bit-rate) and as a result the image has a low quality.

The condition (MAXD2−MAXD1)>T1, respectively (MAXD2−MAXD1)>T1 in above algorithms could also be expressed in the form of ratios or more in general relations between the values of MAXD1 and MAXD2 e.g. by (MAXD2/MAXD1)>T1 or (MAXD2/MAXD1)<1/T1 depending on whether MAXD1 or MAXD2 is the largest. Using the difference provides for a very simple and straightforward method. Using a ratio may be more advantageous for images in which there are large differences in pixel value or the ranges of the pixel values are not a priori known. The sign of the difference MAXD2-MAXD1 is determined by the ratio MAXD2/MAXD1 so that the any condition in relation to said sign could also be expressed in relation to the ratio MAXD2/MAXD1, i.e. whether or not said ratio is larger or smaller than 1.

FIG. 6 illustrates the method when applied for analysis in a vertical dimension. The analysis area or window AWV (vertical analysis window) is divided by line d into two sub-areas AWV1 and AWV2. The calculation of MAXD1 and MAXD2 are then:

MAXD1=max(|V1−V2|,|V2−V3|,|U1−V1|,|W1−V1|,U2−V2|,|W2−V2|,|U3−V3,|W3−V3|);

MAXD2=max(|V4−V5|,|V5−V6|,|U4−V4|,|W4−V4|,|U5−V5|,|W5−V5|,|U6−V6|,|W6−V6|);

The algorithm is comparable to the algorithm as described above, except that Y1, Y2 etc are replaced by V1, V2 etc.

The above figures illustrate the method in relation to a stationary analysis window. The analysis window is, in the method in accordance with the invention scanned over an image or a part of the image. FIG. 7A illustrates that during horizontal analysis the horizontal analysis window AWH is shifted along a horizontal line until a line Y1, Y2, Y3 etc is completely covered, where after the analysis window AWH is shifted downward by a line as schematically shown in FIG. 7B.

FIGS. 8A and 8B show the same but for the vertical analysis using the vertical analysis window AWV. This analysis window is scanned along a vertical line until the analysis is applied to a complete vertical line V1, V2 etc (see FIG. 8A) where after the analysis window is shifted in a horizontal direction (see FIG. 8B) to proceed with scanning along the neighboring vertical line.

The threshold values Tmax, T1, and also possibly T2, T3 etc, may be the same for the horizontal as for the vertical analysis, but may differ. For instance if the original data were interlaced the thresholds are preferably higher for vertical analysis than for horizontal analysis.

It is remarked that the method in accordance with the present invention does not require exact definition of the direction of the edge. Known methods such as the one disclosed in US-20040184669 do require exact definition of the direction of an edge. It is relatively simple to find such edges if the dominant edge has straight horizontal or vertical direction. But if the edge has arc, non-linear shape, or there is a 90-degree angle of the object edge this is not the case. Such edges will require complex two-dimension filtering mechanisms.

The invention uses one-dimensional filtering sequentially horizontally preferably followed vertically in a direction perpendicular with the sub-window with the maximum local gradient. It is not required to define the exact direction of the edge and change the filtering window. Because during calculation of maximum gradient of sub-windows MAXD1 and MAXD2 local gradients of both directions are analyzed, the dominant object edge of any shape and direction will be detected.

It is remarked that the method may be applied to a whole image or to a part of the image.

In short the invention may be described by:

In a method, receiver and display device a compressed data stream is decompressed. Decompression may cause ringing effect. In order to reduce ringing effects an analysis window (AWH, AWV) is used, which is divided into two sub-areas (AWH1, AWH2, AWV1, AWV2) along a dividing line d. For each of the sub-areas a maximum pixel value gradient (MAXD1, MAXD2) is determined, wherein gradients are determined in two directions. If the maximum of all gradients (max(MAXD1, MAXD2) exceeds a threshold (max(MAXD1, MAXD2)>Tmax), low pass filtering is applied, provided that the difference between the maximum gradients for each of the areas is above a threshold (|MAXD2-MAXD1|>T1). The direction of low pass filtering is determined by the sign of the difference of the between the maximum pixel value gradient for the sub-areas.

The invention is also embodied in any computer program product for a method or device in accordance with the invention. Under computer program product should be understood any physical realization of a collection of commands enabling a processor—generic or special purpose-, after a series of loading steps (which may include intermediate conversion steps, like translation to an intermediate language, and a final processor language) to get the commands into the processor, to execute any of the characteristic functions of an invention. In particular, the computer program product may be realized as data on a carrier such as e.g. a disk or tape, data present in a memory, data traveling over a network connection—wired or wireless-, or program code on paper. Apart from program code, characteristic data required for the program may also be embodied as a computer program product.

Some of the steps required for the working of the method may be already present in the functionality of the processor instead of described in the computer program product, such as data input and output steps.

It should be noted that the above-mentioned embodiments illustrate rather than limit the invention, and that those skilled in the art will be able to design many alternative embodiments without departing from the scope of the appended claims.

In the claims, any reference signs placed between parentheses shall not be construed as limiting the claim.

The word “comprising” does not exclude the presence of other elements or steps than those listed in a claim. The invention can be implemented by means of hardware comprising several distinct elements, and by means of a suitably programmed computer. In a device claim enumerating several means, several of these means can be embodied by one and the same item of hardware. The invention may be implemented by any combination of features of various different preferred embodiments as described above.

1. A method of processing a compressed image data stream in which method ringing is reduced wherein an area (AWH, AWV) of an image is selected and divided into two sub-areas of substantially equal size along a dividing line (d), and a first maximum pixel value gradient (MAXD1) between adjacent pixels is established for one of the sub-areas and a second maximum pixel value gradient (MAXD2) for the other sub-area and low pass filtering is applied on the condition that
the maximum of the first and second maximum pixel value gradient (max(MAXD1, MAXD2)) is above a first threshold (Tmax) and
a relation between the first and second maximum pixel value gradient meets a second threshold (|(MAXD2−MAXD1)|>T1)
wherein the low pass filtering is performed perpendicular to the dividing line (d) and wherein the low pass filtering is applied in dependence on the sign of the difference between the first and second maximum pixel value gradients.

2. A method of processing a compressed image data stream as claimed in claim 1, wherein the first threshold is a fixed number.

3. A method as claimed in claim 1, wherein the first threshold is dependent on the pixel values in the area (AWH, AWV).

4. A method as claimed in claim 1, wherein the area comprises n*m pixels, wherein n is the number of pixels perpendicular to the dividing line, and wherein n is even and m is odd.

5. A method as claimed in claim 4, wherein m=6 and n=3.

6. A display device (39) comprising a receiver for receiving a compressed image data stream (21) for displaying an image, the display device comprising a ringing reducer (34) for reduction of ringing artifacts in a displayed decompressed image, wherein the ringing reducer is arranged for selecting an area (AWH, AWV) of an image and dividing it into two sub-areas of substantially equal size along a dividing line (d), and for establishing a first maximum pixel value gradient (MAXD1) between adjacent pixels for one of the sub-areas and a second maximum pixel value gradient (MAXD2) for the other sub-area and for applying low pass filtering on the condition that
the maximum of the first and second maximum pixel value gradient (max(MAXD1, MAXD2)) is above a first threshold (Tmax) and
a relation between the first and second maximum pixel value gradient meets a second threshold (|(MAXD2−MAXD1)|>T1)
wherein the ringing reducer is arranged for performing the low pass filtering perpendicular to the dividing line (d) and application of the low pass filtering in dependence on the sign of the difference between the first and second maximum pixel value gradients.

7. A display device as claimed in claim 6, wherein the first threshold is a fixed number.

8. A display device as claimed in claim 6, wherein the first threshold is dependent on the pixel values in the area (AWH, AWV).

9. A display device as claimed in claim 6, wherein the area comprises n*m pixels, wherein n is the number of pixels perpendicular to the dividing line, and wherein n is even and m is odd.

10. A display device as claimed in claim 9, wherein m=6 and n=3.

11. A receiver for receiving a compressed image data stream (21) for displaying an image, the receiver comprising a ringing reducer (34) for reduction of ringing artifacts in a displayed decompressed image, wherein the ringing reducer is arranged for selecting a area of an image and dividing it into two sub-areas of substantially equal size along a dividing line (d), and for establishing a first maximum pixel value gradient (MAXD1) between adjacent pixels for one of the sub-areas and a second maximum pixel value gradient (MAXD2) for the other sub-area and for applying low pass filtering on the condition that
the maximum of the first and second maximum pixel value gradient (max(MAXD1, MAXD2)) is above a first threshold (Tmax) and
a relation between the first and second maximum pixel value gradient meets a second threshold (|(MAXD2−MAXD1)|>T1)
wherein the ringing reducer is arranged for performing the low pass filtering perpendicular to the dividing line (d) and application of the low pass filtering in dependence on the sign of the difference between the first and second maximum pixel value gradients.

12. A receiver as claimed in claim 11, wherein the first threshold is a fixed number.

13. A receiver as claimed in claim 11, wherein the first threshold is dependent on the pixel values in the area.

14. A receiver as claimed in claim 11, wherein the area comprises n*m pixels, wherein n is the number of pixels perpendicular to the dividing line, and wherein n is even and m is odd.

15. A receiver as claimed in claim 14, wherein m=6 and n=3.

16. Computer program product to be loaded by a computer arrangement, comprising instructions to process a compressed data stream, for a method as claimed in claim 1, when run on a computer, the computer arrangement comprising processing means.
